(19) United States
(12) Patent Application Publication
(10) Pub. No.: US 2015/0206811 A1
(43) Pub. Date: Jul. 23, 2015

(54) SEMICONDUCTOR DEVICE

(71) Applicant: KABUSHIKI KAISHA TOSHIBA, TOKYO (JP)

(72) Inventor: Eitaro MIYAKE, Hyogo (JP)

(21) Appl. No.: 14/474,045

(22) Filed: Aug. 29, 2014

(30) Foreign Application Priority Data
Jan. 21, 2014 (JP) 2014-008769

(51) Int. Cl. H01L 23/043; H01L 21/52; H01L 23/00

(52) U.S. Cl. CPC H01L 23/043; H01L 23/564; H01L 21/52

(57) ABSTRACT

According to one embodiment, a semiconductor device includes a semiconductor chip including a first terminal surface and a second terminal surface located on a side opposite to the first terminal surface. An insulation unit surrounds an outer circumference of a side surface of the semiconductor chip. A metal unit is disposed between the side surface of the semiconductor chip and an inner side surface of the insulation unit.

### CROSS-REFERENCE TO RELATED APPLICATION

This application is based upon and claims the benefit of priority from Japanese Patent Application No. 2014-008769, filed Jan. 21, 2014, the entire contents of which are incorporated herein by reference.

### FIELD

Embodiments described herein relate generally to a semiconductor device.

### BACKGROUND

A pressure contact semiconductor device includes a semiconductor chip configured for the switching of high current, such as that encountered in large industrial equipment applications, electric railway vehicles, and electrical stations and sub-stations or the like. The semiconductor chip, as a result of switching of the large current, can catastrophically fail, leading to ejection of parts thereof, e.g., when a high temperature failure of the semiconductor chip occurs. When this type of failure occurs, not only the semiconductor chip, but also the components provided around the semiconductor chip and constituting the pressure contact semiconductor device, similarly burst or fragment as a result of the energy released when the semiconductor chip fails. In such a case, fragments thus produced may be ejected from the device.

### DESCRIPTION OF THE DRAWINGS

FIGS. 1(A) and 1(B) are a cross-sectional view and a perspective view, respectively, illustrating an example structure of a semiconductor device according to an embodiment.

FIG. 2 is a perspective view illustrating an example structure of a metal explosion-proof unit.

FIG. 3 is a perspective view illustrating an example structure of the metal explosion-proof unit and an insulation buffering unit.

### DETAILED DESCRIPTION

In general, according to one embodiment, there is provided a semiconductor device configured to reduce ejection of, i.e., fragments of a semiconductor chip and components around the semiconductor chip during failure of the semiconductor device.

According to one embodiment, a semiconductor device includes a semiconductor chip including a first terminal surface and a second terminal surface located on a side opposite to the first terminal surface, which in one embodiment, together provide a high current switching semiconductor device. An insulation unit surrounds an outer circumference of a side surface of the semiconductor chip. A metal containment unit is disposed between the side surface of the semiconductor chip and an inner side surface of the insulation unit. The metal containment unit is configured to contain any fragments of the semiconductor chip, and absorb at least part of the energy released upon a failure thereof, so as to reduce or eliminate the incidence of fragmentation of additional components of the device, such as the insulation unit.

An embodiment of the invention is hereinafter described with reference to the drawings. This embodiment is presented by way of example only.

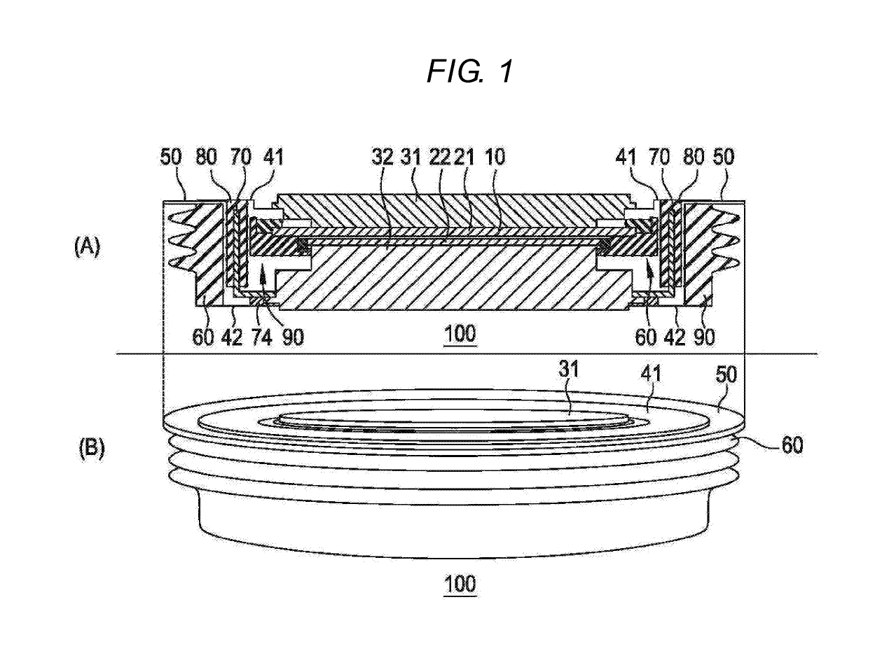

FIG. 1(A) and FIG. 1(B) are a cross-sectional and a perspective view, respectively, illustrating an example of a semiconductor device 100 according to this embodiment. The semiconductor device 100 is not limited to a particular device but may be any type of device. For example, the illustrated semiconductor device 100 is a pressure contact semiconductor device incorporated in facilities such as electrical generating facilities or stations, sub-stations, electric trains, or others, and used for the purpose of switching a large current (2,000 A or larger, for example).

The semiconductor device 100 includes a semiconductor chip 10 configured for power switching, buffering units 21 and 22, electrode units 31 and 32, connection units 41 and 42, a sealing unit 50, an insulation unit 60, a metal explosion-proof unit 70, an insulation buffering unit 80, and an insulation protection unit 90 formed into a generally disk shaped package wherein the semiconductor chip 10 is protected from the environment surrounding the device by being sealed therein, and the structure of the device 100 provides protection against the ejection of fragments of the semiconductor chip 10, and adjacent elements of the device 100, in the event of failure of the device 100.

The semiconductor chip 10 is an element for switching current, and includes transistors and interconnections (not shown) formed on a silicon substrate, for example. The upper surface and the lower surface of the semiconductor chip 10 (as viewed in FIGS. 1A and 1B constitute a pair of terminals (conductors or electrodes), configured to allow flow of the current from the upper surface side to the rear surface side, or from the rear surface side to the upper surface side, of the device. For example, a high voltage is applied to the upper surface of the semiconductor chip 10 functioning as a first terminal surface. On the other hand, the rear surface of the semiconductor chip 10 as a second terminal surface is maintained at ground potential. The gate and gate contact of the semiconductor chip 10 is omitted from this discussion. The ground potential does not represent the reference (0 V) of the entire circuit, but represents the reference potential of the semiconductor element (reference of a gate potential).

The buffering unit 21 is provided on the upper (in reference to the orientation of the device of FIG. 1A) surface of the semiconductor chip 10. The buffering unit 22 is provided on the rear surface (in reference to the orientation of the device of FIG. 1A) of the semiconductor chip 10. The buffering units 21 and 22 are provided in order to lessen thermal stresses, induced by differences in the thermal expansion of the semiconductor chip 10 and the electrodes 31, 32, as well as stress on the semiconductor chip 10 from the pressing of the electrode units 31 and 32 when the electrode units 31 and 32 of the semiconductor device 100 are brought into press contact with the semiconductor chip 10 each other, i.e., when the device 100 is positioned in n external circuit and external contacts of the external circuit press the electrode units 31 and 31 toward each other. The buffering units 21 and 22 are made of conductive metal such as molybdenum and thus form an electrically conductive path between the semiconductor chip 10 and the electrode units 31 and 32.

The electrode unit 31 is provided on the upper side (in reference to the orientation of the device of FIG. 1A) of the buffering unit 21. The electrode unit 32 is provided on the lower side (in reference to the orientation of the device of FIG. 1A) of the buffering unit 22. The electrode unit 31 is electrically connected with the upper surface (in reference to the orientation of the device of FIG. 1A) (first terminal surface) of the semiconductor chip 10 via the buffering unit 21. The electrode unit 32 is electrically connected with the rear or bottom surface (in reference to the orientation of the device of FIG. 1A) (second terminal surface) of the semiconductor chip 10 via the buffering unit 22. In the embodiment of the device 100 illustrated, the bottom electrode comprises two parts, a first bottom electrode portion 32a having a first diameter or cross section, and a second bottom electrode portion 32b, physically and electrically interconnected within the device 100. The electrode units 31 and 32 are made of conductive metal such as copper.

The connection unit 41 is provided on and about the circumferential edge of the electrode unit 31. The connection unit 42 is provided on and about the circumferential edge of the electrode unit 32. The connection unit 41 is disposed between the electrode unit 31 and the sealing unit 50 or between the electrode unit 31 and the insulation unit 60. The connection unit 42 is disposed between the electrode unit 32 and the insulation unit 60. The connection units 41 and 42 are provided to extend outwardly from the electrode units 31 and 32 across any gaps in the upper or lower side surfaces of the device 100 to seal of the internal elements and structure of the device 100, including the semiconductor chip 10 and other elements surrounded by the insulation unit 60, from the external ambient environment, while exposing the front surface or rear surface of the electrode units 31 and 32 to the exterior of the device 100 for interconnection thereto into a switching circuit, and thus connection unit 41 spans from contact with the outer circumference of the electrode 31 to, and is connected to, sealing unit 50, and connection unit 42 spans from contact with the lower electrode 32 to insulation unit 60. It is preferable that each of the connection units 41 and 42 are made of conductive metal having high mechanical strength and a high melting point. For example, the connection unit 41 is made of copper, whereas the connection unit 42 is made of an alloy of iron and nickel. Since the connection unit 42 is made of a conductive material, it is possible to electrically connect the metal explosion-proof unit 70 with the electrode unit 32 and thus maintain them at the same potential.

The insulation unit 60 is provided and extends between the connection unit 41 and the connection unit 42, with a portion of the sealing unit 50 forming an interface between connection unit 41 and the insulation unit 60. The insulation unit 60 is disposed to surround the outer circumference of the side surface of the semiconductor chip 10. As illustrated in (B) in FIG. 1, the insulation unit 60 has a cylindrical shape, and is made of insulation material such as ceramic. The insulation unit 60 seals the semiconductor chip 10 and others in cooperation with the connection units 41 and 42. The insulation unit 60 is provided in order to insulate between the connection unit 41 and the connection unit 42, and between the electrode unit 31 and the electrode unit 32, and thus has an undulating outer circumferential surface to increase the string distance from connection unit 41 to connection unit 42 across its surface, and thereby reduce the likelihood of a breakdown and arc therebetween along the surface of the insulation unit 60.

The metal explosion-proof unit 70 is disposed between the side surface of the semiconductor chip 10 and the inner side surface of the insulation unit 60, i.e., within the circumference of the insulation unit 60 and around the circumference of the semiconductor chip 10, and it thus surrounds the circumference or perimeter of the semiconductor chip 10. The metal explosion-proof unit 70 is a sleeve shaped unit having an outer circumferential wall and an inwardly extending, lower annular flange which is configured to reduce the likelihood of blowout (scatter or ejection) of fragments of the semiconductor chip 10and other device components toward the outside of the semiconductor device 100 when the semiconductor chip 10 is damaged or catastrophically fails such as by bursting, and thus also protects the insulation unit 70 from being struck by such fragments which would otherwise lead to fracturing and potential ejection of portions of the insulation unit 70 from the device.

The metal explosion-proof unit 70 is an annular, generally ring shaped member which is L-shaped in cross section, and is electrically connected with the electrode unit 32 via the connection unit 42. The metal explosion-proof unit 70 having an L shape is configured to have high mechanical strength against impact and cracking, and is easily connected with the connection unit 42. The metal explosion-proof unit 70 is made of conductive metal such as copper, which is ductile and can absorb the energy of impact of fragments of the semiconductor chip and other device components it surrounds by bending or deforming in the event of a chip 10 failure events. Since the metal explosion-proof unit 70 is excellent in mechanical strength, it is possible to effectively reduce blowout or ejection of fragments when the semiconductor chip 10 is damaged or bursts. The metal explosion-proof unit 70, which is electrically connected with the electrode unit 32, is maintained at the ground potential. Accordingly, the potential of the metal explosion-proof unit 70 is not a floating potential, thereby reducing the possibility of noise generation from the semiconductor chip 10 caused by the metal explosion-proof unit 70.

The insulation buffering unit 80 is provided to at least partially cover the portions of the metal explosion-proof unit 70 extending upwardly from the bottom to top of the device in the orientation thereof shown in FIG. 1A, and is disposed between that portion of the metal explosion-proof unit 70 and the insulation unit 60, and between that portion of the metal explosion-proof unit 70 and the semiconductor chip 10, i.e., on either side of the metal explosion proof unit 70 where the metal explosion proof unit 70 is formed as an annular ring shape and is located adjacent to the outer periphery of the electrodes and the inner periphery of the insulating unit 70. The insulation buffering unit 80 is provided to surround the circumference of the semiconductor chip 10 similarly to the metal explosion-proof unit 70. The insulation buffering unit 80 is made of an electrically insulating material having physical elasticity such as silicone rubber.

When the insulation buffering unit 80 is absent, there is a possibility that the metal explosion-proof unit 70 would sufficiently deform by burst or explosion of the semiconductor chip 10 to collide with the insulation unit 60. When this collision occurs, the insulation unit 60 is damaged, in which case fragments of the insulation unit 60 may be scattered. On the other hand, according to this embodiment, the insulation buffering unit 80 is provided between the metal explosion-proof unit 70 and the insulation unit 60, and between the metal explosion-proof unit 70 and the semiconductor chip 10. The insulation buffering unit 80 functions as a shock absorber, wherefore the metal explosion-proof unit 70 deformed by bursting of the semiconductor chip 10 does not directly collide with the insulation unit 60, i.e., it or fragments thereof are contained by the elastic properties of the insulation buffering unit 80, and the energy of impact is at least partially absorbed by the elasticity thereof, preventing the fragments from reaching the insulation unit 80 or reducing their energy such that impact thereof with the interior surface of the insulation unit 80 does not cause the insulation unit 80 to fracture. Accordingly, the insulation buffering unit 80 may reduce direct collision between the metal explosion-proof unit 70 and the insulation unit 60, thereby reducing damage to the insulation unit 60 in the case of failure of the semiconductor chip 10.

The insulation buffering unit 80 is made of electrically insulating material. Thus, the insulation buffering unit 80 may reduce short-circuit (discharge) between the metal explosion-proof unit 70 and the electrode unit 31 or between the metal explosion-proof unit 70 and the buffering unit 21.

The insulation protection unit 90 is provided on the side surface (outer edge) of the semiconductor chip 10, and on the side surfaces (outer edges) of the buffering units 21 and 22. The insulation protection unit 90 is made of insulation material such as a resin which encapsulates, i.e., surrounds, the outer annular edge of the buffering unit 21, and extends across the edges of the semiconductor chip 10 and buffering unit 23. The insulation protection unit 90 protects the side surface of the semiconductor chip 10 and the side surfaces of the buffering units 21 and 22. Moreover, the insulation protection unit 90 prevents short-circuiting between the terminal surface on the front side of the semiconductor chip 10 and the terminal surface on the rear side of the semiconductor chip 10, and short-circuiting between the buffering unit 21 and the buffering unit 22.

The metal explosion-proof unit 70 and the insulation buffering unit 80 surround, or the metal explosion-proof unit 70 or the insulation buffering unit 80 surrounds, the circumference of the insulation protection unit 90 as well as the semiconductor chip 10. According to this structure, the metal explosion-proof unit 70 and/or the insulation buffering unit 80 may reduce blowout (scatter or ejection) of the insulation protection unit 90 from the device even when the insulation protection unit 90 is melted by the heat of the semiconductor chip 10 during a failure thereof.

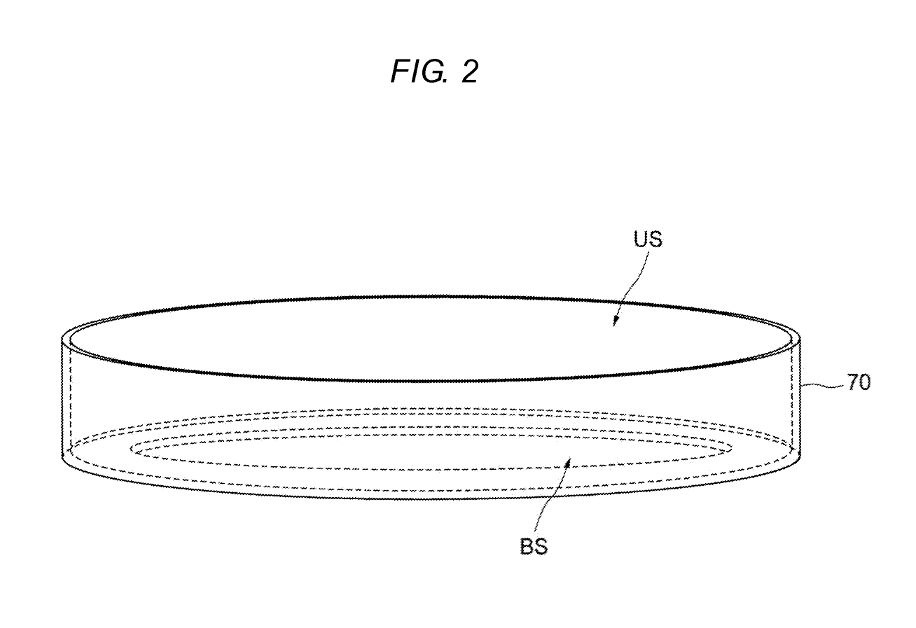

FIG. 2 is a perspective view illustrating a structure example of the metal explosion-proof unit 70. As illustrated in FIG. 2, the metal explosion-proof unit 70 has a cylindrical shape. An upper surface US of the metal explosion-proof unit 70 is generally open, while a bottom surface BS of the metal explosion-proof unit 70 is partially opened at the center of the bottom surface BS. At the lower circumference of the bottom surface BS of the metal explosion-proof unit 70 an annular flange extends inwardly thereof. Accordingly, the metal explosion-proof unit 70 has a substantially L-shaped cross section as illustrated in (A) in FIG. 1. The metal explosion proof unit 70 may be adhered to the connection unit 42 using a conductive adhesive such as silver solder or silver paste 74.

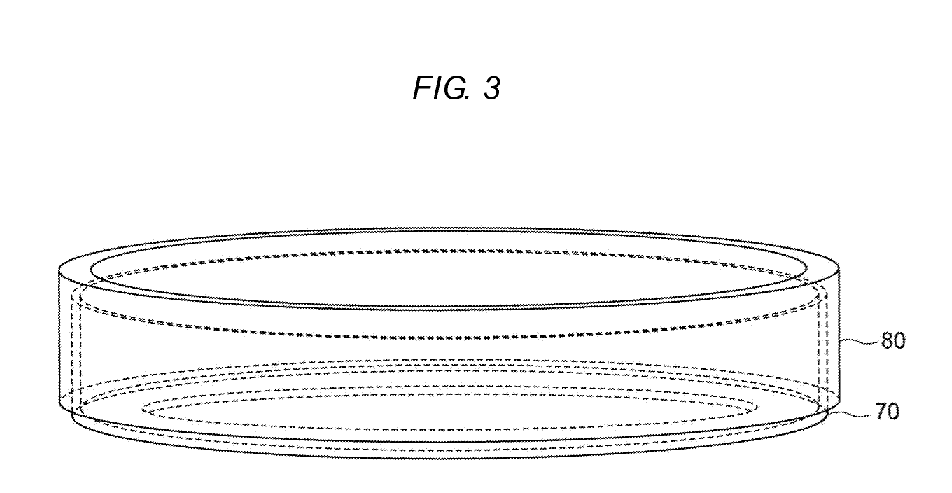

FIG. 3 is a perspective view illustrating a structure example of the metal explosion-proof unit 70 and the insulation buffering unit 80. As illustrated in FIG. 3, the insulation buffering unit 80 is provided to cover the upper part of the cylindrical upwardly extending cylindrical wall of the metal explosion-proof unit 70. The insulation buffering unit 80 is formed or inserted over the upper surface, the inner side surface and the outer side surface of the cylindrical upwardly extending wall of the metal explosion-proof unit 70. Accordingly, the insulation buffering unit 80 has a cylindrical shape similarly to the metal explosion-proof unit 70, but without the inwardly extending lower annular wall. The insulation buffering unit 80 and the metal explosion-proof unit 70 thus constructed are positioned inside the insulation unit 60, and adhered to the upper side of the connection unit 42. Accordingly, the metal explosion-proof unit 70 and the insulation buffering unit 80 are disposed between the outer side surface of the semiconductor chip 10 and the inner side surface of the insulation unit 60 to surround the circumference of the semiconductor chip 10.

According to this embodiment, the metal explosion-proof unit 70 disposed between the outer side surface of the semiconductor chip 10 and the inner side surface of the insulation unit 60 are so formed as to surround the circumference of the semiconductor chip 10 and form a containment therefore upon failure of the semiconductor chip. Accordingly, the metal explosion-proof unit 70 may reduce blowout (scatter or ejection) of fragments of the semiconductor chip 10, fragments of the insulation unit 60, or other device elements from the semiconductor device 100 when the semiconductor chip 10 is damaged or bursts.

When an explosion-proof component made of only resin (such as silicone resin and Teflon®) is provided inside the semiconductor device without providing the metal explosion-proof unit 70, since the resin has lower mechanical strength and heat resistance than those of metal, it is difficult to sufficiently reduce blowout or ejection of fragments upon a failure of the semiconductor chip 10. Moreover, the melting point of resin such as silicone resin and Teflon ® is at most approximately 300° C., and is therefore rather lower than the melting point (approximately 1,400° C.) attained by a semiconductor chip (such as silicon chip) upon a heat related failure thereof. Thus, the explosion-proof component made of resin is insufficient in view of mechanical strength, and insufficient in view of resistance to high temperatures.

On the other hand, the metal explosion-proof unit 70 according to this embodiment is made of metal material. In this case, the semiconductor device 100 according to this embodiment is capable of obtaining sufficient strength for burst or explosion of the semiconductor chip 10, and obtaining sufficient resistance to high temperatures, to contain the chip fragments from being ejected from the device upon a failure of the semiconductor chip 10.

Moreover, the metal explosion-proof unit 70 according to this embodiment is maintained at ground potential. Accordingly, the potential of the metal explosion-proof unit 70 does not float, which condition avoids the possibility of noise generation from the semiconductor chip 10 caused by the metal explosion-proof unit 70.

Furthermore, according to this embodiment, the area (cylindrical portion) between the outer side surface of the semiconductor chip 10 and the inner side surface of the insulation unit 60, corresponding to the metal explosion-proof unit 70, is covered by the insulation buffering unit 80. The insulation buffering unit 80 may reduce the chance or incidence of electrical short-circuiting between the metal explosion-proof unit 70 and the components around the semiconductor chip 10, and also may reduce the chance or incidence of contact between the metal explosion-proof unit 70 and the components around the semiconductor chip 10.

Accordingly, the semiconductor device 100 according to this embodiment has excellent explosion-proof strength and heat resistance, and therefore may reduce blowout or ejection of fragments of the semiconductor chip 10 and the components around the semiconductor chip 10 from the semiconductor device upon a failure thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor chip including a first terminal surface and a second terminal surface located on a side opposite to the first terminal surface;
an insulation unit surrounding an outer circumference of a side surface of the semiconductor chip; and
a metal unit disposed between the side surface of the semiconductor chip and an inner side surface of the insulation unit.

2. The device according to claim 1, further comprising:
an insulation buffering unit disposed between the metal unit and the insulation unit and between the metal unit and the semiconductor chip.

3. The device according to claim 2, wherein the metal unit and the insulation buffering unit surround the circumference of the semiconductor chip.

4. The device according to claim 2, further comprising:
an insulation protection unit provided on an outer edge of the semiconductor chip to insulate between the first terminal surface and the second terminal surface of the semiconductor chip,
wherein the metal unit and the insulation buffering unit surround the semiconductor chip and the insulation protection unit.

5. The device according to claim 1, further comprising:
a first electrode unit connected with the first terminal surface of the semiconductor chip; and
a second electrode unit connected with the second terminal surface of the semiconductor chip,
wherein the metal unit is electrically connected with the second electrode unit.

6. The device according to claim 1, wherein a potential of the second electrode unit is at ground potential.

7. The device according to claim 1, wherein the metal unit surrounds the circumference of the semiconductor chip.

8. The device according to claim 1, further comprising:
an insulation protection unit provided on an outer edge of the semiconductor chip to insulate between the first terminal surface and the second terminal surface of the semiconductor chip,
wherein the metal unit surrounds the semiconductor chip and the insulation protection unit.

9. A method of protecting against ejection of portions of a high current semiconductor device upon failure thereof, comprising:
providing a semiconductor circuit on a semiconductor chip, the semiconductor chip disposed between opposed electrodes;
surrounding the semiconductor chip with an insulating unit; and
positioning a ductile metal component sleeve intermediate of the insulation unit and the semiconductor chip and in a surrounding relationship to the semiconductor chip.

10. The method of claim 9, further comprising positioning an elastic electrical insulator intermediate of the semiconductor chip and the metal sleeve.

11. The method of claim 10, further comprising positioning the elastic electrical insulator intermediate the metal sleeve and the insulation unit.

12. The method of claim 10, wherein the elastic electrical insulator is configured as an annular member extending over the upper surface and sides of the sleeve.

13. The method of claim 10, further comprising:
extending a first conductive covering from one side of the insulation unit to the first of the opposed electrodes; and
extending a second conductive covering from one side of the insulation unit to the second of the opposed electrodes.

14. The method of claim 10, further comprising positioning a first buffering unit between a first of the opposed electrodes and the semiconductor chip and a second buffering unit between a second of the opposed electrodes and the semiconductor chip.

15. The method of claim 14, further comprising surrounding the periphery of the semiconductor chip and the buffering units in an insulating resin.

16. A high current semiconductor switching device, comprising:
a semiconductor chip including a first terminal surface and a second terminal surface located on a side opposite to the first terminal surface;
an insulation unit surrounding an outer circumference of a side surface of the semiconductor chip; and
a ductile metal sleeve disposed between the side surface of the semiconductor chip and an inner side surface of the insulation unit.

17. The high current switching semiconductor switching device of claim 16, wherein an elastic electrically insulating member is disposed over the surface of the sleeve facing the semiconductor device.

18. The high current switching semiconductor switching device of claim 17, wherein an elastic electrically insulating member is disposed over the surface of the sleeve facing the insulation unit.

19. The high current switching semiconductor switching device of claim 17, wherein an insulating resin is disposed over the outer edge of the semiconductor chip.

20. The high current switching semiconductor switching device of claim 16, wherein the sleeve surrounds the circumference of the semiconductor chip.
